(19) United States
(12) Patent Application Publication
(10) Pub. No.: US 2026/0110082 A1
(43) Pub. Date: Apr. 23, 2026

(54) METHOD FOR PRODUCING GRAPHITE FLUORIDE GRANULES

(71) Applicant: APPLIED MATERIALS, INC., Santa Clara, CA (US)

(72) Inventors: Vijay Tripathi, Uattat Pradesh (IN); Naga Ravikumar Varma Nadimpalli, Bangalore-Karnataka (IN); Vijay Bhan Sharma, Rajasthan (IN); Pratap Maity, West Bengal (IN); Jayesh Shinde, Maharashtra (IN); Mahesh Chelvaraj Arcot, Thane-Maharashtra (IN); Guttula Mohan Kumar, Pincode (IN)

(21) Appl. No.: 18/921,413

(22) Filed: Oct. 21, 2024

(51) Int. Cl. C23C 16/44; B01D 53/047; B01J 20/20; B01J 20/28; B01J 20/32; C23C 16/30; C23C 16/515

(52) U.S. Cl. CPC C23C 16/4417; B01D 53/047; B01J 20/20; B01J 20/28004; B01J 20/28016; B01J 20/3204; B01J 20/3217; B01J 20/3231; B01J 20/3293; C23C 16/30; C23C 16/515; B01D 2253/102; B01D 2253/25; B01D 2253/304; B01D 2253/306; B01D 2253/311

(57) ABSTRACT

A method of manufacturing granules is provided. The method includes flowing an inert gas and a fluorine-containing gas into a plasma source at a first ratio; generating a fluorine-containing plasma from the inert gas and the fluorine-containing gas by the plasma source; and applying the fluorine containing plasma to porous carbon granules in process chamber. The fluorine-containing plasma reacts with a surface of the carbon granules to form a carbon fluoride layer on the surface of the carbon granules.

### TECHNICAL FIELD

The present application relates to a method for producing graphite fluoride granules using a plasma source and carbon granules.

### BACKGROUND

Many processes, such as processes for forming semiconductors, photovoltaics, displays, etc., use one or more gases to deposit layers, etch layers, clean substrates, and so on. For some processes a plasma is formed and used during deposition, etching, cleaning, etc. Currently, the gases used to generate radicals for these processes (e.g. NF₃, F₂, etc.) pose potential environmental hazard and can result in excessive wear of processing equipment.

In semiconductor processing, radical species are often used for various processing operations in a chamber. For example, a radical species, such as atomic fluorine, may be used in an etching or a chamber cleaning process. Radical species can be formed by various processes. One process to generate radical species is to use a plasma. For example, a fluorine containing gas is flowed into the chamber, and the plasma breaks the compound into elemental fluorine. Radical species are highly chemically reactive.

To reduce the effects of the radicals and other hazardous materials, filters have been incorporated into the processes. Some of these filters may include granules, such as carbon granules. Currently, the process to produce these granules include several steps, which can be time consuming, and which include wet chemistry. Further, the granules produced can contain surface particles, which reduce the effectiveness of the granules in the process chamber to capture radicals and other hazardous materials in the process chamber.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In one aspect of the disclosure, a method is provided. The method includes flowing an inert gas and a fluorine-containing gas into a plasma source at a first ratio and generating a fluorine-containing plasma from the inert gas and the fluorine-containing gas by the plasma source. The method may further include applying the fluorine-containing plasma to porous carbon granules in a process chamber. The fluorine-containing plasma may react with a surface of the carbon granules to form a carbon fluoride layer on the surface of the carbon granules.

In another aspect of the disclosure, a granule is provided. The granule incudes a porous carbon having a pore volume of about 0.1 cm3/g to about 2 cm3/g and a surface area of about 750 m2/g to about 1500 m2/g; and a carbon fluoride layer on a surface of the porous carbon body, wherein the carbon fluoride layer may be on surfaces of a plurality of pores of the porous carbon body.

In yet another aspect of the disclosure, a pressure swing adsorption (PSA) filter is provided. The PSA filter may include a container; and a plurality of granules in the container. Each granule of the plurality of granules may include a porous carbon body having a pore volume of about 0.1 cm3/g to about 2 cm3/g and a surface area of about 750 m2/g to about 1500 m2/g. Each granule may also have a carbon fluoride layer on a surface of the porous carbon body, wherein the carbon fluoride layer is on surfaces of a plurality of pores of the porous carbon body.

### BRIEF DESCRIPTION OF THE DRAWINGS

The present disclosure is illustrated by way of example, and not by way of limitation in the figures of the accompanying drawings.

FIG. 1 is a sectional side view of a substrate processing system including a pressure adsorption filter, according to some embodiments.

FIG. 2 is a flow chart of one embodiment of a method for preparing the carbon granules.

FIG. 3 is an illustration of a system to generate granules according to some embodiments.

FIG. 4 is a PSA bed including a container filled with granules according to an embodiment.

FIG. 5A is an illustration of a single particle with a coating according to an embodiment.

FIG. 5B is a zoomed in view of an inner pore that has been coated according to an embodiment.

### DETAILED DESCRIPTION

In the manufacturing of semiconductors and other devices, carbon granules may be used to remove any unwanted materials post processing in the process chamber. For example, carbon granules can be used in a pressure swing adsorption (PSA) bed to remove any gases that may pose potential environmental hazard. However, the current carbon granules are expensive to make and costly to use in processing chambers. The present disclosure describes a carbon granule with a graphite fluoride coating and a method of manufacturing such a carbon granule to address these issues. The carbon granules of the present disclosure are prepared to have a higher surface area and pore volume to improve adsorption than traditional granules. The method to produce the carbon granules described herein provides a fluorinated carbon granule without using wet chemistry, and with minimal processing steps. Thus, the method is more efficient and less costly than traditional techniques for manufacturing graphite fluoride granules. The manufactured fluorinated carbon granules can then be used in a pressure swing adsorption (PSA) filter, which in some embodiments may be installed in an exhaust line of a processing chamber.

The method of producing fluorinated carbon granules includes preparing porous carbon granules and placing the carbon granules in a process chamber. The method includes flowing an inert gas (e.g., Ar) and a fluorine-containing gas (e.g., NF₃) into a plasma source (e.g., a remote plasma source or a local plasma source) at a first ratio, generating a fluorine-containing plasma from the inert gas and the fluorine-containing gas by the plasma source, and flowing the fluorine-containing plasma into the process chamber. The fluorine containing plasma may be applied to the porous carbon granules in the process chamber. The fluorine-containing plasma may react with the surface of the porous carbon granules, forming a layer of graphite fluoride at the surface of the porous carbon granules. This may include forming the layer of graphite fluoride on the surfaces of pores (e.g., on pore walls) of the porous carbon granules. By using the process chamber to fluorinate the carbon granules, the amount of fluorine applied can be controlled by adjusting the ratio between the fluorine-containing gas and the inert gas. The ratio can be adjusted to achieve a target fluorine amount in the layer formed on the surface of the carbon granules.

In embodiments, the novel fluorinated carbon granules that are produced in the method include a porous carbon body having a pore volume of about 0.1 cm³/g to about 2 cm³/g and a surface area of about 750 m²/g to about 1500 m²/g and a carbon fluoride layer on the surface of the porous carbon body. The fluorinated carbon granules may then be used for filtration purposes in embodiments. The carbon fluoride layer of the granule reacts with unwanted byproducts or hazardous chemicals, depending on use, allowing the granule to absorb them into the porous carbon body. Because the pore volume and surface area are higher than current granules used in the industry, the carbon granules may not have to be changed as frequently and allow for a longer processing time between purge and/or cleaning cycles of the carbon granules. Additionally, an efficiency of the fluorinated graphite granules may be greater than the efficiency of traditional carbon granules and of fluorinated graphite granules manufactured using traditional techniques.

Embodiments of the present disclosure relate to a method for manufacturing fluorinated graphite granules in a process chamber to produce fluorinated carbon granules that can be used to absorb unwanted byproducts and/or hazardous material from a system. Conventional methods of manufacturing involves a series of several steps to produce the carbon granules, including a wet chemistry step which can be expensive and timely to complete. In embodiments described herein, a carbon granule including a carbon fluoride layer (also referred to as a graphite fluoride layer) on a surface of the porous carbon body is provided such that the carbon fluoride layer is on surfaces of a plurality of pores of the porous carbon body. In embodiments described herein, a pressure swing adsorption (PSA) filter is manufactured that includes the graphite fluoride granules manufactured as described.

In some embodiments, a method includes flowing an inert gas and a fluorine-containing gas into a plasma source at a first ratio; generating a fluorine-containing plasma from the inert gas and the fluorine-containing gas by the plasma source; and applying the fluorine-containing plasma to porous carbon granules in a process chamber. In some embodiments, the fluorine-containing plasma reacts with a surface of the carbon granules to form a carbon fluoride layer on the surface of the carbon granules.

In some embodiments, a plasma power of about 50 Watts to about 1000 Watts may be applied at the plasma source. In some embodiments, the applied plasma power may be about 50 Watts to about 950 Watts, about 100 Watts to about 900 Watts, about 150 Watts to about 850 Watts, about 200 Watts to about 800 Watts, about 250 Watts to about 750 Watts, about 300 Watts to about 700 Watts, about 350 Watts to about 650 Watts, about 400 Watts to about 600 Watts, or about 450 Watts toa about 550 Watts, or any value or sub-range.

In some embodiments, the ratio of the inert gas to the fluorine-containing gas may be about 10:1 to about 3:1. In some embodiments, the ratio of the inert gas to the fluorine-containing gas may be about 10:1, about 9:1, about 8:1, about 7:1, about 6:1 about 5:1, about 4:1, or about 3:1.

In some embodiments, the fluorine-containing gas may include F₂, NF₃, CF₃O, CF₄, SF₆, or a combination thereof. In some embodiments, the inert gas may include nitrogen (N), argon (Ar).

In some embodiments, a first flow rate of the inert gas may be about 100 sccm to about 3500 sccm. In some embodiments, the first flow rate of the inert gas may be about 100 sccm to about 3400 sccm, 200 sccm to about 3300 sccm, about 300 sccm to about 3000 sccm, about 500 sccm to about 2800 sccm, about 750 sccm to about 2500 sccm, about 1000 sccm to about 2250 sccm, about 1250 sccm to about 2000 sccm, or about 1500 sccm to about 1750 sccm. In some embodiments, a second flow rate of the fluorine-containing gas may be about 50 sccm to about 500 sccm. In some embodiments, the second flow rate of the fluorine-containing gas may be about 50 sccm to about 450 sccm, about 75 sccm to about 400 sccm, about 100 sccm to about 350 sccm, about 150 sccm to about 300 sccm, or about 200 sccm to about 250 sccm.

In some embodiments, the method may further include maintaining the porous carbon granules at a temperature of about 25° C. to about 500° C., while applying the fluorine-containing plasma to the porous carbon granules. In some embodiments, the temperature may be from about 25° C. to about 475° C., about 50° C. to about 450° C., about 75° C. to about 425° C., about 100° C. to about 400° C., about 125° C. to about 375° C., about 150° C. to about 350° C., about 175° C. to about 325° C., about 200° C. to about 300° C., or about 225° C. to about 275° C.

In some embodiments, the method may further include applying a plurality of pulses of the fluorine containing plasma to the porous carbon granules, wherein for each pulse of the plurality of pulses the fluorine-containing plasma is applied to the porous carbon granules for about 10 seconds to about 60 seconds. In some embodiments, each pulse may be applied for about 10 seconds, about 20 seconds, about 30 seconds, about 40 seconds, about 50 seconds, or about 60 seconds. In some embodiments, the plurality of pulses may include about 50 to 150 pulses, about 60 to about 140 pulses, about 70 to about 130 pulses, about 80 to about 120 pulses, or about 90 to about 110 pulses.

In some embodiments, the method may further include manufacturing one or more pressure swing adsorption beds using the carbon granules having the carbon fluoride layer.

In some embodiments, the carbon fluoride layer may form on surfaces of a plurality of pores of the porous carbon granule.

In another embodiment, carbon granules are provided. The carbon granules include a porous carbon body having a pore volume of about 0.1 cm³/g to about 2 cm³/g and a surface area of about 750 m²/g to about 1500 m²/g and a carbon fluoride layer on a surface of the porous carbon body, wherein the carbon fluoride layer is on surface of a plurality of pores of the porous carbon body. In some embodiments, the porous carbon body may have a pore volume of about 0.1 cm³/g to about 1.8 cm³/g, about 0.2 cm³/g to about 1.7 cm³/g, about 0.3 cm³/g to about 1.5 cm³/g, about 0.5 cm³/g to about 1.2 cm³/g, or about 0.8 cm³/g to about 1.0 cm³/g. In some embodiments, the porous carbon body may have a surface area of about 750 m²/g to about 1450 m²/g, about 800 m²/g to about 1400 m²/g, about 850 m²/g to about 1350 m²/g, about 900 m²/g to about 1300 m²/g, about 950 m²/g to about 1250 m²/g, about 1000 m²/g to about 1200 m²/g, or about 1050 m²/g to about 1150 m²/g.

In some embodiments, the carbon fluoride layer of the carbon granule may include fluorine in at least about 90 wt %. In some embodiments, the amount of fluorine in the carbon fluoride later may be at least about 90 wt %, at least about 92 wt %, at least about 95 wt %, at least about 98 wt %, or at least about 99 wt %.

In some embodiments, a total amount of fluorine in the carbon fluoride granule may be about 15 wt % to about 75 wt %. In some embodiments, the total amount of fluorine in the carbon fluoride granule may be about 20 wt % to about 75 wt %, about 25 wt % to about 70 wt %, about 30 wt % to about 65 wt %, about 35 wt % to about 60 wt %, about 40 wt % to about 55%, or about 45 wt % to about 50 wt %.

In some embodiments, the carbon fluoride granule may be particle free. In other embodiments, the carbon fluoride granule may be substantially free of particles.

In some embodiments, the carbon fluoride layer may have a thickness of about 300 nm to about 500 microns. In some embodiments, the carbon fluoride layer may have a thickness of about 300 nm to about 450 microns, about 400 nm to about 450 microns, about 500 nm to about 400 microns, about 600 nm to about 350 microns, about 700 nm to about 300 microns, about 800 nm to about 250 microns, about 900 nm to about 200 microns, about 1 micron to about 150 microns, about 10 microns to about 120 microns, about 20 microns to about 100 microns, or about 50 microns to about 75 microns.

In an embodiment, a pressure swing adsorption (PSA) filter is provided. The PSA filter may include a container and a plurality of carbon fluoride granules in the container. Each granule of the plurality of carbon fluoride granules may include a porous carbon body having a pore volume of about 0.1 cm³/g to about 2 cm³/g and a surface area of about 750 m²/g to about 1500 m²/g, and a carbon fluoride layer on a surface of the porous carbon body. The carbon fluoride layer may be on surfaces of a plurality of pores of the porous carbon body.

In some embodiments, the porous carbon body may have a pore volume of about 0.1 cm³/g to about 1.8 cm³/g, about 0.2 cm³/g to about 1.7 cm³/g, about 0.3 cm³/g to about 1.5 cm³/g, about 0.5 cm³/g to about 1.2 cm³/g, or about 0.8 cm³/g to about 1.0 cm³/g. In some embodiments, the porous carbon body may have a surface area of about 750 m²/g to about 1450 m²/g, about 800 m²/g to about 1400 m²/g, about 850 m²/g to about 1350 m²/g, about 900 m²/g to about 1300 m²/g, about 950 m²/g to about 1250 m²/g, about 1000 m²/g to about 1200 m²/g, or about 1050 m²/g to about 1150 m²/g.

In an embodiment, the PSA filter may be used in a process chamber including a recirculation system. In another embodiment, the PSA filter may be used for a process chamber and placed after the exhaust of the process chamber. The PSA filter may be used in other uses and other industries outside of a process chamber. For example, it may be used in any system that benefits from filtering of byproducts or chemicals that use a carbon granule.

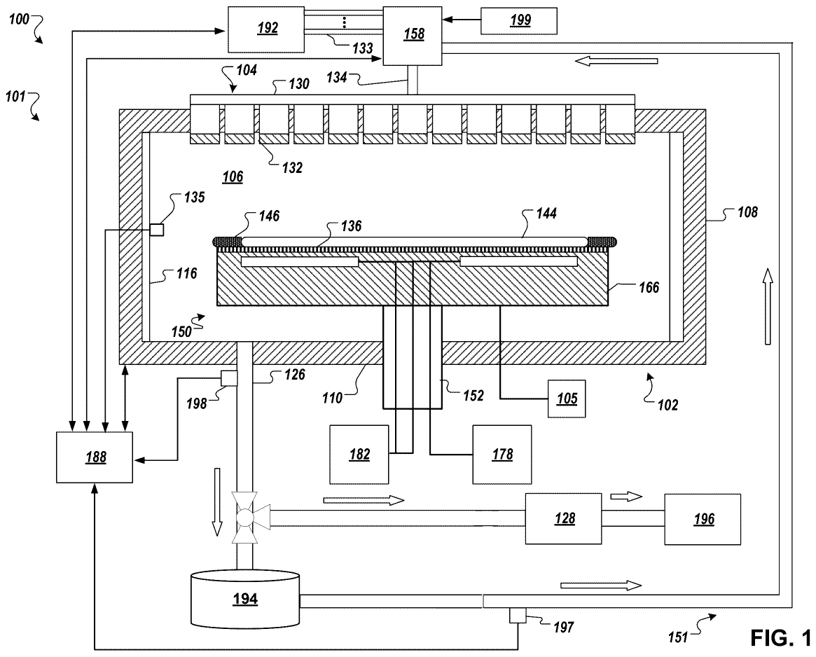

Referring now to the figures, FIG. 1 is a sectional view of a manufacturing system 100 that performs plasma-based processes in embodiments including a PSA filter 194 that includes the carbon fluoride granules of the present disclosure. The manufacturing system 100 may include a gas panel 192 connected to a plasma source 158 via one or more gas delivery lines. In some embodiments, the plasma source 158 may be a remote plasma source (RPS). The gas delivery lines 133 may deliver gases such as process gases (e.g., chemical vapor deposition (CVD) precursors, ALD precursors, etch gases, cleaning gases (e.g., fluorine containing gases such as NF₃), carrier gases such as Ar, and so on. In embodiments, a different gas delivery line 133 may be used for each of the gases that may be delivered to plasma source 158.

In one embodiment, gas panel 192 controls the initial concentration of NF₃ and Ar gas that flows into the plasma source 158. In embodiments, the gas panel 192 may be configured to deliver at least one gas to the plasma source 158. In some embodiments, the at least one gas includes NF₃, F₂, C₂F₆, SF₆, SiCl₄, HBr, NF₃, CF₄, CHF₃, CH₂F₃, Cl₂ and SiF₄, Ar, N₂, He, or a combination thereof.

The manufacturing system may further include a process chamber 101 coupled to plasma source 158 via one or more plasma delivery lines 134. A power source 199 may provide power to the plasma source 158. The plasma source 158 may generate a plasma, from one or more of the gases from gas panel 192, and may deliver the plasma (e.g., a gas containing the plasma) to the process chamber 101 via the one or more plasma delivery lines 134.

The process chamber 101 may be, for example, a plasma etch reactor, a deposition chamber, etc. The process chamber 101 may be suitable for an etching operation, a deposition operation, a chamber cleaning operation, a plasma treatment operation, or any other type of operation typical of a semiconductor manufacturing facility. For example, the processing chamber may be configured for performing CVD, ALD, plasma-based etching, and so on.

In an embodiment, one or more substrates (e.g., wafers) 144 may be provided within the process chamber 101. In an embodiment, process chamber 101 may be maintained at a pressure suitable for a target operation. In a particular embodiment, the pressure may be between approximately 1 Torr and approximately 200 Torr. The process chamber 101 is aged over time by the exposure the processing gases and materials. This aging results in retention of processing species or byproduct species that affect the effective concentration of active processing species in the processing chambers.

The process chamber 101 and/or plasma source 158 may be connected to a controller 188, which may control processing of the plasma source 158, process chamber 101 (e.g., by controlling set points, loading recipes, and so on), and/or the recirculation of recycled exhaust gases. A radical sensor 135 may be connected to the plasma delivery line(s) 133 and/or may be disposed within the process chamber 101 to detect a concentration of radicals in a gas or plasma delivered by the plasma source 158 to process chamber 101. In embodiments, the plasma source 158 includes or is connected to power source 199 that is connected to deliver plasma-generating power to an energy conduit and/or to a gas distribution assembly that is further connected to a gas outlet configured to deliver excited gases to the process chamber 101. In some embodiments, one or more settings of the plasma source 158 include a power provided to the plasma source 158 by the power source. Another setting for the plasma source 158 may include a plasma frequency. Other settings that may affect a generated plasma (e.g., a concentration of fluorine radicals in a generated plasma) include a pressure in process chamber 101, flow rates of one or more gases (e.g., process gasses such as NF process time, and so on. In some embodiments, the excited gases provided from plasma source 158 to process chamber 101 include fluorine radicals (e.g., F*). In some embodiments the gases provided from plasma source 158 to process chamber 101 further include NF₃, F₂, NF, NF₂, or a combination thereof.

In some embodiments, the excited gases may include nitrogen-based radicals.

In embodiments, the fluorine and/or nitrogen-based radicals react with silicon based compounds in the processing chamber to form SiF₄ as a gaseous byproduct. This may occur, for example, during a cleaning process while not product substrate is disposed within the process chamber 101.

As indicated, in some embodiments the one or more settings of the plasma source 158 include a power output by the power source 199. In embodiments, controller 188 adjusts one or more settings of at least one of the plasma source 158 or the process chamber 101 based on the measured concentration of fluorine radicals in the process chamber 101 measured by radical sensor 135. In some embodiments, the one or more settings of at least one of the plasma source 158 or the process chamber 101 includes at least one of a pressure within the process chamber, a flow of excited gases to the process chamber, a power of the plasma source, or a frequency of the plasma.

In an embodiment, the manufacturing system 100 may comprise a radical sensor 135 that is fluidically coupled to the process chamber 101 and/or to the plasma delivery line(s) 134. For example, a valve may be provided along a tube between the process chamber 101 and the radical sensor 135. In an embodiment, the valve is a type of valve that allows for an unobstructed line of sight between the process chamber 101 and the radical sensor 135. For example, the valve may be an isolation gate valve. An isolation gate valve may allow for a binary state of operation. That is, the valve may be open (i.e., 1) or closed (i.e., 0). When the valve is open, the line of sight is unobstructed. Alternately, another type of valve such as a needle valve may be used.

In embodiments, the radical sensor 135 comprises a piezoelectric substrate in a holder. The piezoelectric substrate is made to oscillate at a resonant frequency by applying an alternating current to the piezoelectric substrate. One or more surface of the piezoelectric substrate is coated by a film that is reactive to a narrow range of molecular species. In particular, the film is composed of a material that is reactive to a target molecular species of a particular target gas from among gases being used in a process. In one embodiment, the radical sensor comprises a QCM having at least one coated surface that is coated with a film that is selectively reactive to radicals of a particular gas. The radical sensor 135 is described in greater detail below with reference to the proceeding figures.

In some embodiments, the radical sensor 135 is a QCM sensor. The QCM sensor base may include a thin plate of quartz crystal that oscillates in the thickness-shear mode because such a QCM sensor base has high sensitivity to mass change on the crystal. The piezoelectric nature of quartz crystal allows the crystal to be driven into oscillation and with its resonant frequency measured by simple electrical means. In embodiments, the quartz crystal is precisely cut at certain angles with respect to its crystallographic axes. In embodiments, the quartz crystal is an AT-cut quartz crystal.

In some embodiments, radical sensor 135 is a QCM sensor having a coating that is reactant to fluorine radicals. In one embodiment, QCM sensor includes a silicon dioxide coating, or other coating that acts as a filter to react with fluorine radicals.

In one embodiment, in order to measure an amount of positively and/or negatively charged radicals, a pair of radical sensors may be used. A first radical sensor may include the charged gratings, and a second radical sensor may not include the charged gratings. All radicals of a target gas species may be detected by the second radical sensor, and only neutral radicals of the target gas species may be detected by the first radical sensor. A difference between the measurements of the two radical sensors may then be computed to determine an amount of the radicals detected by the second radical sensor that were attributable to charged radicals. The grating may be modified to only filter out positively charged molecules/ions or to only filter out negatively charged molecules. Accordingly, by combining two or more radical sensors, each with a different grating configuration (e.g., one not including any grating), an amount of positively charged radicals may be detected, an amount of negatively charged radicals may be detected, and/or an amount of neutral radicals may be detected.

In embodiments, the plasma source 158 is a remote plasma source (RPS) that generates plasma at a remote location and delivers the externally generated plasma to the process chamber 101. Alternatively, the process chamber 101 may include an integrated plasma source (not shown) that can generate plasma within the processing chamber. In either instance, the radical sensor 135 may be disposed within or connected to the process chamber 101 rather than in or connected to the gas deliver lines 133 in embodiments.

Process chamber 101 includes a substrate support assembly 150, according to some embodiments. Substrate support assembly 150 includes a puck 166 (e.g., may include an electrostatic chuck (ESC)). The puck 166 may perform chucking operations, e.g., vacuum chucking, electrostatic chucking, etc. Substrate support assembly 150 may further include a base plate, a cooling plate and/or an insulator plate (not shown).

Process chamber 101 includes chamber body 102 and lid 104 that enclose an interior volume 106. Chamber body 102 may be fabricated from aluminum, stainless steel, or other suitable material. Chamber body 102 generally includes sidewalls 108 and a bottom 110. An outer liner 116 may be disposed adjacent to side walls 108, e.g., to protect chamber body 102. Outer liner 116 may be fabricated and/or coated with a plasma or halogen-containing gas resistant material. Outer liner 116 may be fabricated from or coated with aluminum oxide. Outer liner 116 may be fabricated from or coated with yttria, yttrium alloy, oxides thereof, etc.

Lid 104 may be supported on sidewall 108 of chamber body 102. Lid 104 may be openable, allowing access to interior volume 106. Lid 104 may provide a seal for process chamber 101 when closed. Plasma source 158 may be coupled to process chamber 101 to provide process, cleaning, backing, flushing, etc., gases and/or plasmas to interior volume 106 through gas distribution assembly 130. Gas distribution assembly 130 may be integrated with lid 104.

Examples of processing gases that may be used in process chamber 101 include halogen-containing gases, such as C₂F₆, SF₆, SiCl₄, HBr, NF₃, CF₄, CHF₃, CH₂F₃, Cl₂ and SiF₄. Other reactive gases may include O₂ or N₂O. Non-reactive gases may be used for flushing or as carrier gases, such as N₂, He, Ar, etc. Gas distribution assembly 130 (e.g., showerhead) may include multiple apertures 132 on the downstream surface of gas distribution assembly 130. Apertures 132 may direct gas flow to the surface of substrate 144. In some embodiments, gas distribution assembly may include a nozzle (not pictured) extended through a hold in lid 104. A seal may be made between the nozzle and lid 104. Gas distribution assembly 130 may be fabricated and/or coated by a ceramic material, such as silicon carbide, yttrium oxide, etc., to provide resistance to processing conditions of process chamber 101.

Substrate support assembly 150 is disposed in interior volume 106 of processing chamber 101 below gas distribution assembly 130. Substrate support assembly 150 may hold a substrate 144 during processing. An inner liner (not shown) may be coated on the periphery of substrate support assembly 148. The inner liner 118 may share features (e.g., materials of manufacture, function, etc.) with outer liner 116.

Substrate support assembly 150 may include supporting pedestal 152, insulator plate, base plate, cooling plate, and puck 166. Puck 166 may include electrodes 536 for providing one or more functions. Electrodes may include chucking electrodes (e.g., for securing substrate 144 to an upper surface of puck 166), heating electrodes, RF electrodes for plasma control, etc.

Protective ring 146 (e.g. a process kit ring, an insert ring, and/or a support ring) may be disposed over a portion of puck 166 at an outer perimeter of puck 166. Puck 166 may be coated with a protective layer (not shown). Protective layer 136 may be a ceramic such as Y₂O₃ (yttria or yttrium oxide), Y₄Al₂O₉ (YAM), Al₂O₃ (alumina), Y₃Al₅O₁₂ (YAG), YAlO₃ (YAP), quartz, SiC (silicon carbide), Si₃N₄ (silicon nitride), Sialon, AlN (aluminum nitride), AlON (aluminum oxynitride), TiO₂ (titania), ZrO₂ (zirconia), TiC (titanium carbide), ZrC (zirconium carbide), TiN (titanium nitride), TiCN (titanium carbon nitride), Y₂O₃ stablized ZrO₂ (YSZ), and so on. The protective layer may be a ceramic composite such as YAG distributed in an alumina matrix, a yttria-zirconia solid solution, a silicon carbide-silicon nitride solid solution, or the like. The protective layer may be sapphire or MgAlON.

Puck 166 may further include multiple gas passages such as grooves, mesas, and other features that may be formed in an upper surface of puck 166. Gas passages may be fluidly coupled to a gas source 105. The gas outlet 105 further delivers SiO₂, H₂, or a combination thereof. Gas from gas source 105 may be utilized as a heat transfer or backside gas, may be utilized for control of one or more lift pins of puck 166, etc. Multiple gas sources may be utilized (not shown). Gas passages may provide a gas flow path for a backside gas such as He via holes drilled in puck 166. Backside gas may be provided at a controlled pressure into gas passages to enhance heat transfer between puck 166 and substrate 144.

Puck 166 may include one or more clamping electrodes. The clamping electrodes may be controlled by chucking power source 182. Clamping electrodes may further couple to one or more RF power sources through a matching circuit for maintaining a plasma formed from process and/or other gases within process chamber 101. The RF power sources may be capable of producing an RF signal having a frequency from about 50 kilohertz (kHz) to about 3 gigahertz (GHz) and a power of up to about 10,000 Watts. Heating electrodes of puck 166 may be coupled to heater power source 178.

An exhaust line 126 may connect to chamber body 102, and may couple interior volume 106 to a pump system 128 and/or to a recirculation system 151. Pump system 128 may include one or more pumps, valves, lines, manifolds, tanks, etc., utilized to evacuate and regulate the pressure of interior volume 106. Exhaust line 126 may include a valve that may direct gases to pump system 128 and/or to a filtration system 194 including one or more pressure swing adsorption (PSA) filters. In embodiments the PSA filters include graphite fluoride granules manufactured in accordance with embodiments of the present disclosure. The filtration system 194 may be connected to pump system 128 and/or to recirculation system 151.

In embodiments, a second sensor 198 may be coupled to the exhaust line 126. The second sensor 198 may be connected to the exhaust line 126 upstream of the filtration system 194 to measure the concentration of one or more gases in an exhaust from process chamber 101. In one embodiment, second sensor 198 is configured to measure a concentration of one or more silicon-containing species in the exhaust. In one embodiment, second sensor 198 is configured to measure an amount of SiF₄ in the exhaust. In one embodiment, the second sensor 198 includes a non-dispersive infrared (NDIR) sensor and/or a radical sensor. Other types of sensors may also be used. In one embodiment, second sensor 198 is configured to measure at least one of NF₃ or fluorine radicals in the exhaust. In some embodiments, second sensor 198 is connected to controller 188 to provide sensor measurements to controller 188. Based on sensor measurements from second sensor 198, controller 188 may determine an amount of silicon that is being removed from an interior of process chamber 101. A silicon-containing film may build up on exposed surfaces of the interior volume 106 of process chamber during deposition processes in embodiments. Cleaning processes may periodically be performed to remove the buildup of silicon-containing film. As the film is reduced, the amount of silicon-containing species in the exhaust may also be reduced. This information may be used by controller 188 to determine how close a clean process is to complete and/or whether a clean process is complete. For example, if no silicon-containing species are detected, then controller 188 may determine that a clean process is complete. If a reduced amount of silicon-containing species is detected (e.g., an amount less than a threshold), then controller 188 may determine that a clean process is close to complete. This may prompt controller 188 to adjust a clean process (e.g., by reducing an amount of fluorine-containing gas (e.g., NF₃) to plasma source, by reducing a plasma power, by reducing a plasma frequency, etc.). This may reduce a chance that the process chamber 101 is exposed to more fluorine-based plasma after cleaning is complete.

In embodiments, manufacturing system 100 includes recirculation system 151, which recirculates at least a portion of the exhaust from process chamber 101 back to plasma source 158. Fluorine-containing gases may be expensive, and may also be substantial greenhouse gases. Accordingly, it is beneficial in embodiments to reduce an amount of fluorine-based gases that are used in processes such as plasma-based processes. Often not all of the fluorine (or other active species) in a plasma get used. As a result, the exhaust from process chamber 101 may contain useful gases that could be reused. Reuse of such useful gases (e.g., F₂, Ar, etc.) may reduce an amount of gases that are supplied to plasma source 158 from gas panel 192. Accordingly, recirculation system 151 recirculates some gases in exhaust back to plasma source 158 in embodiments.

In embodiments, there are some gases in exhaust from process chamber 101 that could be harmful to plasma source 158 and/or that are not useful. Accordingly, in some embodiments a filtration system 194 including the PSA filter is disposed between exhaust line 126 and recirculation line 151. The PSA filter may include carbon granules with graphite fluoride layers as described herein, which may filter out gases that might be harmful to plasma source 158 and/or that may not be useful, and may allow useful gases such as Ar and F₂ to pass through.

In some embodiments, the filtration system 194 includes a pressure swing adsorption (PSA) filter. The filtered exhaust stream output by the filtration system 194 may be a fluorine rich gas stream. In some embodiments, the fluorine rich gas stream may include at least about 90% fluorine, at least about 92% fluorine, at least about 95% fluorine, at least about 98% fluorine, or at least about 99% fluorine. Filtered out gases may be trapped in filter 194 to pump system 128, while target gases such as Ar and/or F₂ may pass through filter 194 to recirculation system 151.

Pump system 128 may output exhaust gases that have not been provided to recirculation system 151 to an abatement system 196. Abatement system 196 may dispose of the output gases, such as by burning the output gases in the exhaust.

In some embodiments, filter 194 is a pressure swing adsorption (PSA) bed filter. PSA is a technology that may be used in gas separation and purification processes. Pressure Swing Adsorption operates by using adsorbent materials (such as the granules described herein) in a bed through which a gas mixture (e.g., in the exhaust) is passed. In embodiments, the granules include a porous carbon body having a pore volume of about ^{0.1} cm³/g to about 2 cm³/g and a surface area of about 750 m²/g to about 1500 m²/g. In some embodiments, the porous carbon body may have a pore volume of about 0.1 cm³/g to about 1.8 cm³/g, about 0.2 cm³/g to about 1.7 cm³/g, about 0.3 cm³/g to about 1.5 cm³/g, about 0.5 cm³/g to about 1.2 cm³/g, or about 0.8 cm³/g to about 1.0 cm³/g. In some embodiments, the porous carbon body may have a surface area of about 750 m²/g to about 1450 m²/g, about 800 m²/g to about 1400 m²/g, about 850 m²/g to about 1350 m²/g, about 900 m²/g to about 1300 m²/g, about 950 m²/g to about 1250 m²/g, about 1000 m²/g to about 1200 m²/g, or about 1050 m²/g to about 1150 m²/g. The granules may further have a carbon fluoride layer on a surface of the porous carbon body. The carbon fluoride layer may be on surfaces of pores of the porous carbon body. It is believed that that the carbon fluoride layer may react with the gases to adsorb the gases in the porous carbon body, the carbon fluoride layer, or a combination of both.

In some embodiments of the granules, the carbon fluoride layer may include fluorine in at least about 90 wt %, at least about 92 wt %, at least about 95 wt %, at least about 98 wt %, or at least about 99 wt %. In some embodiments of the granules, a total amount of fluorine in the granule is about 15 wt % to about 75 wt %, about 15 wt % to about 70 wt %, about 20 wt % to about 75 wt %, about 25 wt % to about 75 wt %, about 30 wt % to about 65 wt %, about 35 wt % to about 60 wt %, or about 40 wt % to about 55 wt %.

In some embodiments, the granule may be particle free. In other embodiments, the granule may be substantially free of particles. In the current manufacturing methods to prepare granules for adsorption, the granules may include particles from the process that influences the effectiveness of the adsorption of the particles. The particles include impurities, oxygen, or a combination thereof.

In some embodiments, the carbon fluoride layer of the granule may have a composition of CFₓ, where x is 0.5 to 1.1. In some embodiments, the carbon fluoride layer may have a thickness of about 300 nm to about 500 microns. In some embodiments, the carbon fluoride layer may have a thickness of about 300 nm to about 450 microns, about 400 nm to about 450 microns, about 500 nm to about 400 microns, about 600 nm to about 350 microns, about 700 nm to about 300 microns, about 800 nm to about 250 microns, about 900 nm to about 200 microns, about 1 micron to about 150 microns, about 10 microns to about 120 microns, about 20 microns to about 100 microns, or about 50 microns to about 75 microns.

In the PSA filter, different gas components are adsorbed by the material at different pressures, and by altering the pressure, specific gases can be selectively released and collected. PSA may include the steps of adsorption, depressurization, and purge. The adsorption step includes exposing the gas mixture to a high pressure, at which a target gas component or components adhere(s) to the surface of the adsorbent material, and other gases may be pumped out to pump system 128. In a depressurization step, the pressure in the PSA bed filter is reduced, releasing the adhered gas, which may flow to recirculation system 151. In a purge step, another gas may be used to purge the adsorbent bed, removing any residual undesired gases and sending them to pump system 128 and preparing the bed for a next cycle. In embodiments, the PSA bed is configured to adsorb F₂.

In one embodiment, a PSA filter may include pellets (e.g., the graphite fluoride granules discussed in embodiments herein) that adsorb SiF₄. These pellets may be refurbished and/or replaced after the adsorbing potential has deteriorated over prolonged use. In some embodiments. The filter 194 may adsorbs at least one of HF, SiF₄, NF, NF₂, NF₃ N₂, or O₂.

In embodiments, the filter 194 may direct excess SiF₄, HF, or any other non-target gases to a pump 128. In some embodiments, the pump 128 may direct the flow of filtered materials to abatement system 196.

In embodiments, one or more first compounds that are filtered out by the filter 194 include at least one of SiF₄ or HF, and one or more second compounds that are separated out from the exhaust and sent to recirculation system 151 include at least one of the fluorine radicals or argon.

In some embodiments, a third sensor 197 (e.g., a gas sensor) may be connected to recirculation system 151 to detect a concentration of one or more gases in the recirculation line. The third sensor 197 may be configured to detect and measure at least one of F₂, SiF₄, HF, Ar, N₂, or O₂. The third sensor 197 may determine a concentration of F₂ that is being provided back to plasma source 158 in embodiments. Controller 188 may control an amount of fluorine that is provided to plasma source 158 in embodiments. Controller 188 may receive measurements from third sensor 197 to determine an amount of fluorine that is delivered to plasma source 158 from recirculation system 151. Controller 188 may determine a target amount of fluorine to be delivered to plasma source 158, and may subtract the amount of fluorine provided by recirculation system 151 from the target amount of fluorine. A remaining difference in amount of fluorine may be provided by a fluorine-rich gas (e.g., NF₃) from gas panel 192. Accordingly, controller 192 may reduce an amount of NF₃ or other fluorine-containing gas delivered to plasma source 158 from gas panel 192 based on the data from third sensor 197 in embodiments.

In some embodiments, argon plasma may be maintained in the process chamber 101 to keep particles suspended and prevent deposition on chamber processing surfaces. In embodiments, a cleaning process may generate silicon nitride in the process chamber 101 that is additionally filtered out and removed. In some embodiments, the filter 194 may be configured to receive an exhaust from the processing chamber 101 via the exhaust line 126. The filter 194 may filter out one or more first compounds from the exhaust and provide a semi filtered exhaust to an additional filter (not pictured), which may filter out additional one or more first compounds and provide a filtered exhaust that includes one or more second compounds to the recirculation controller 192, one or more of which may be measured by third sensor 197 and reported to controller 188. In embodiments, the third sensor 197 downstream of the filter 194 measures the concentration of the fluorine radicals in the filtered exhaust. In some embodiments, the controller 188 may further adjust the one or more settings of at least one of the plasma source 158 or the process chamber 101 based on the measured concentration of the at least one of NF₃ of the fluorine radicals in the exhaust, such as described above.

As touched on above, controller 188 (also referred to as a system controller) may control one or more parameters and/or set points of the plasma source 158 and/or process chamber 101. Controller 188 can be and/or include a computing device such as a personal computer, a server computer, a programmable logic controller (PLC), a microcontroller, and so on. Controller 188 can include one or more processing devices, which can be general-purpose processing devices such as a microprocessor, central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device can also be one or more special-purpose processing devices such as an application specific integrated circuit (ASIC), a field programmable gate array (FPGA), a digital signal processor (DSP), network processor, or the like. Controller 188 can include a data storage device (e.g., one or more disk drives and/or solid state drives), a main memory, a static memory, a network interface, and/or other components. Controller 188 can execute instructions to perform any one or more of the methodologies and/or embodiments described herein. The instructions can be stored on a computer readable storage medium, which can include the main memory, static memory, secondary storage and/or processing device (during execution of the instructions). In embodiments, execution of the instructions by controller 188 causes controller 188 to perform the methods described herein. For example, controller 188 may receive measurements from radical sensor 135 indicating a concentration of a particular species of radicals in a received or generated plasma, may receive measurements from second sensor 198 indicating a concentration of one or more byproduct species that result from the radicals interacting with a surfaces in processing chamber, and/or may receive measurements from third sensor 197 indicating a concentration of one or more target gases to be recirculated back to plasma source 158. Controller 188 may adjust one or more properties or settings (e.g., such as a plasma power, flow rate of one or more gases to plasma source, etc.) of plasma source 158 responsive to the measured radical concentration, the measured byproduct concentration and/or the measured concentration of target gases recirculated to plasma source 158. Controller 188 may additionally adjust one or more properties of process chamber 101, such as pressure. Controller 188 can also be configured to permit entry and display of data, operating commands, and the like by a human operator.

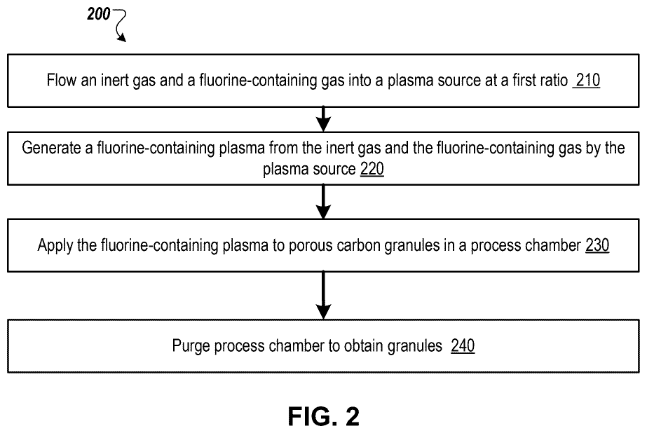

FIG. 2 is a flow chart of for performing the manufacturing method 200 of the granule.

In some embodiments, porous carbon granules are disposed in a boat or other open faced container (e.g., which may be composed of alumina, aluminum nitride, and/or another ceramic material). The boat may be transferred to a process chamber from a load lock by a robot of a transfer chamber in embodiments. In some embodiments, the process chamber is a plasma deposition chamber or a plasma etch chamber that is conventionally configured for processing of wafers. In embodiments, the boat and/or granules may be heated in the process chamber for a time period until the granules reach thermal stability. The process chamber may be maintained at a temperature of about 25° C. to about 500° C., about 50° C. to about 450° C., about 75° C. to about 400° C., about 100° C. to about 350° C., about 125° C. to about 325° C., about 150° C. to about 300° C., about 175° C. to about 275° C., or about 200° C. to about 250° C. The granules may be heated to the temperature of the process chamber in embodiments. In some embodiments, the granules are heated for a time period of about 10 minutes, about 20 minutes, about 25 minutes, about 30 minutes, about 40 minutes, about 50 minutes, about 60 minutes, or another time period. For example, the granules may be heated for about 10-60 minutes to reach thermal equilibrium.

At block 210, an inert gas and a fluorine-containing gas are flowed into a plasma source at a first ratio. In some embodiments, the inert gas and fluorine-containing gas are mixed prior to being flowed to a plasma source. Alternatively, the inert gas and fluorine-containing gas may be mixed at the plasma source. In some embodiments, the first ratio of the inert gas to the fluorine-containing gas may be about 10:1 to about 3:1. In some embodiments, the ratio may be about 10:1, about 9:1, about 8:1 (e.g., 800 sccms of Ar to about 100 sccms of the fluorine-containing gas), about 7:1, about 6:1, about 5:1, about 4:1, or about 3:1. In some embodiments, the inert gas may be N₂, Ar, or a combination thereof, and the fluorine-containing gas may be F₂, NF₃, CF₃O, CF₄, SF₆, or a combination thereof. In some embodiments, the plasma source may be remote plasma source (RPS) or a local plasma source. The plasma source may generate capacitively coupled plasma in some embodiments. Alternatively, or additionally, the plasma source may be a direct current plasma source, a radio frequency plasma source, a microwave plasma source, or other type of plasma source.

At block 220, a fluorine-containing plasma is generated from the inert gas and the fluorine-containing gas by the plasma source. In some embodiments, the inert gas and the fluorine-containing gas may be flowed at different rates to generate a fluorine-containing plasma. In some embodiments, the first flow rate of the inert gas may be about 100 to about 3500 sccm. The first flow rate of the inert gas may also be about 200 sccm to about 3500 sccm, about 300 sccm to about 3250 sccm, about 500 sccm to about 3000 sccm, about 750 sccm to about 2750 sccm, about 1000 sccm to about 2500 sccm, about 1250 sccm to about 2250 sccm, or about 1500 sccm to about 2000 sccm. In some embodiments, the second flow rate of the fluorine-containing gas may be about 50 to about 500 sccm, about 75 to about 450 sccm, about 100 to about 400 sccm, about 150 to about 350 sccm, or about 200 to about 300 sccm. By flowing the inert gas and the fluorine-containing gas at different flow rates, the content of fluorine in the fluorine-containing plasma can be adjusted depending on the target amount of fluorine for the granule.

At block 230, the fluorine-containing plasma is applied to porous carbon granules in the process chamber.

The process chamber may be maintained at a temperature of about 25° C. to about 500° C., about 50° C. to about 450° C., about 75° C. to about 400° C., about 100° C. to about 350° C., about 125° C. to about 325° C., about 150° C. to about 300° C., about 175° C. to about 275° C., or about 200° C. to about 250° C. The temperature may be maintained while applying the fluorine-containing plasma to the porous carbon granules. In some embodiments, a plasma power of about 50 W to about 1000 W may be applied at the plasma source. The plasma power may be about 50 W to about 950 W, about 100 W to about 900 W, about 150 W to about 850 W, about 200 W to about 800 W, about 250 W to about 750 W, about 300 W to about 700 W, about 350 W to about 650 W, about 400 W to about 600 W, or about 450 W to about 550 W. In some embodiments, the fluorine-containing plasma may be applied in a continuous flow.

In some embodiments, the fluorine-containing plasma may be applied by a plurality of pulses to the porous carbon granules. In some embodiments, each pulse may be applied for about 10 seconds to about 60 seconds. Each pulse may be applied for about 10 seconds, about 15 seconds, about 20 seconds, about 30 seconds, about 40 seconds, about 50 seconds, or about 60 seconds. In some embodiments, the plurality of pulses may include about 50 to 150 pulses. In some embodiments, the throttle position of a valve in the process chamber may be adjusted. The throttle position may affect the process of the process chamber. In some embodiments, the throttle valve may be opened in a position of about 10% to about 90%, about 15% to about 85%, about 20% to about 80%, about 35% to about 75 wt %, about 40 wt % to about 70 wt %, about 45 wt % to about 65 wt %, or about 50 wt % to about 60 wt %. In some embodiments, the pressure of the process chamber may be about 1 Torr to about 20 Torr, about 2 Torr to about 18 Torr, about 5 Torr to about 15 Torr, or about 8 Torr to about 12 Torr.

In some embodiments, the total process time from blocks 210 to 230 may be about 10 minutes to about 2 hours, about 20 minutes to about 1.8 hours, about 30 minutes to about 1.5 hours, or about 45 minutes to about 1.25 hours.

After applying the fluorine-containing plasma in block 230, the process chamber is purged to obtain granules having a carbon fluorinated layer as described herein. In particular, the carbon fluorinated layer is on the surface of the porous carbon body. The granules include a porous carbon body having a pore volume of about 0.1 cm³/g to about 2 cm³/g and a surface area of about 750 m²/g to about 1500 m²/g. The surface area as described herein is understood to be a BET surface area as known by one of skill in the art. To purge the process chamber, an inert gas is applied in the process chamber. The purge step may be applied for about 5 minutes to about 2 hours.

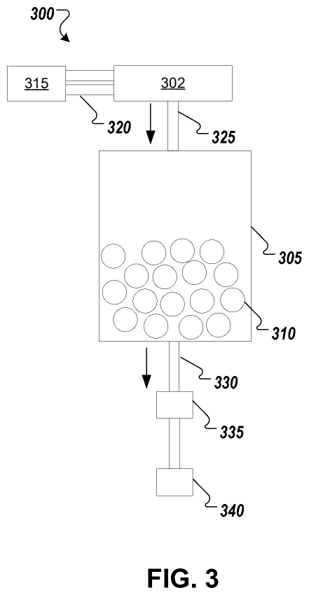

FIG. 3 is an illustration of a system 300 to generate granules 310 according to some embodiments. The system 300 includes a gas source 315 to deliver a process gas and a carrier gas through gas lines 320 to a remote plasma source 302. In some embodiments, the process gas may include a fluorine-containing gas, while the carrier gas may include an inert gas. In some embodiments, the fluorine-containing gas may include F₂, NF₃, CF₃O, CF₄, SF₆, or a combination thereof, while the inert gas may be Ar. In embodiments, a different gas delivery line 320 may be used for each of the gases that may be delivered to the remote plasma source 302. The remote plasma source 302 generates a plasma and delivers a plasma through a plasma delivery line 325 to a chamber 305. In some embodiments, the method of delivering the gas and/or plasma is similar to blocks 210-230 as described in relation to FIG. 2. The chamber 305 may hold granules 310 that are to be processed according to the present disclosure. In some embodiments, the granules are disposed in a boat or other container that is disposed in the chamber 305. The granules 310 may include a porous carbon body. In some embodiments, the granules include a porous carbon body having a pore volume of about 0.1 cm³/g to about 2 cm³/g and a surface area of about 750 m²/g to about 1500 m²/g. The surface area as described herein is understood to be a BET surface area as known by one of skill in the art. When the plasma gas is delivered from the remote plasma source 302, the granules 310 are processed to include a carbon fluorinated layer as described throughout the specification. After applying the plasma to the granules 310 according to the method described herein, the plasma may be pumped out of the chamber 305 through an exhaust line 330 and by pump 335, and may be sent to an abatement system 340.

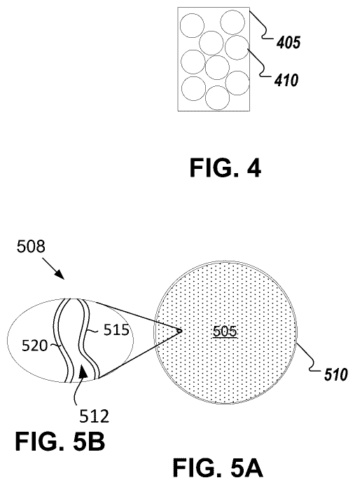

FIG. 4 illustrates a pressure swing adsorption (PSA) bed 405 according to an embodiment of the disclosure. The PSA bed 405 includes granules 410 according to an embodiment. The granules 410 of the PSA bed 405 may include carbon granules having a carbon fluoride layer. In some embodiments of the granules 410, the carbon fluoride layer may include fluorine in at least about 90 wt %, at least about 92 wt %, at least about 95 wt %, at least about 98 wt %, or at least about 99 wt %. In some embodiments, the carbon fluoride layer of the granule 410 may have a composition of CFₓ, where x is 0.5 to 1.1. In some embodiments, the carbon fluoride layer may have a thickness of about 300 nm to about 500 microns. Each granule 410 may include a porous carbon body having a pore volume of about 0.1 cm³/g to about 2 cm³/g and a surface area of about 750 m²/g to about 1500 m²/g, and a carbon fluoride layer on a surface of the porous carbon body. The carbon fluoride layer may be on surfaces of a plurality of pores of the porous carbon body. This can be further seen in FIGS. 5A and 5B.

FIGS. 5A and 5B illustrate a granule 505 having a carbon fluoride layer 510 according to the present disclosure. FIG. 5A is a porous granule 505. The granule 505 may include a porous carbon body having a pore volume of about 0.1 cm³/g to about 2 cm³/g and a surface area of about 750 m²/g to about 1500 m²/g. The granule 505 includes a carbon fluoride layer 510 that is applied according to the method of FIG. 2.

The granule 505 has a plurality of pores, one of which 508 is shown in FIG. 5B. The granule 505 may have a porosity of about 5% to about 80%. Pores 508 may have a surface 515 including a carbon fluoride layer 520, which corresponds to the carbon fluoride layer described herein. The carbon fluoride layer 520 may have a composition of CFₓ, where x is 0.5 to 1.1 on the surface 515 of pore 508. The single layer 520 has little or no impact on the flow path 512 through pore 508 such that even with the single layer 520, the pore 508 is permeable to gases during its normal operation. The carbon fluoride layer 520 or 510 may be grown or deposited on exterior surfaces of the granule 505 as well as on pore walls 515 of pores 508 within the granule 505 using the ALD technique.

The graphite fluoride layer 510 may be a conformal layer of relatively uniform thickness and zero porosity (i.e., porosity-free) on the pore walls 515 of pore 508 despite the complex geometry. The carbon fluoride layer 510, 520 may reduce plasma interactions and improve the granule's durability without impacting its performance. The carbon fluoride layer 510, 520 deposited as discussed in embodiments herein maintains the relative shape and geometric configuration of the pore 508 and of the external surfaces of granule 505 so as to not disturb its functionality.

Unless specifically stated otherwise, terms such as “receiving,” “performing,” “providing,” “obtaining,” “causing,” “accessing,” “determining,” “adding,” “using,” “training,” “reducing,” “generating,” “correcting,” or the like, refer to actions and processes performed or implemented by computer systems that manipulates and transforms data represented as physical (electronic) quantities within the computer system registers and memories into other data similarly represented as physical quantities within the computer system memories or registers or other such information storage, transmission or display devices. Also, the terms “first,” “second,” “third,” “fourth,” etc. as used herein are meant as labels to distinguish among different elements and may not have an ordinal meaning according to their numerical designation.

Examples described herein also relate to an apparatus for performing the methods described herein. This apparatus may be specially constructed for performing the methods described herein, or it may include a general purpose computer system selectively programmed by a computer program stored in the computer system. Such a computer program may be stored in a computer-readable tangible storage medium.

The methods and illustrative examples described herein are not inherently related to any particular computer or other apparatus. Various general purpose systems may be used in accordance with the teachings described herein, or it may prove convenient to construct more specialized apparatus to perform methods described herein and/or each of their individual functions, routines, subroutines, or operations. Examples of the structure for a variety of these systems are set forth in the description above.

The terms “over,” “under,” “between,” “disposed on,” “support,” and “on” as used herein refer to a relative position of one material layer or component with respect to other layers or components. For example, one layer disposed on, over, or under another layer may be directly in contact with the other layer or may have one or more intervening layers. Moreover, one layer disposed between two layers may be directly in contact with the two layers or may have one or more intervening layers. Similarly, unless explicitly stated otherwise, one feature disposed between two features may be in direct contact with the adjacent features or may have one or more intervening layers.

As used herein, the term “substantially free” refers to less than about 10%, less than about 5%, less than about 1%, or less than about 0.1%.

The above description is intended to be illustrative, and not restrictive. Although the present disclosure has been described with references to specific illustrative examples and implementations, it will be recognized that the present disclosure is not limited to the examples and implementations described. The scope of the disclosure should be determined with reference to the following claims, along with the full scope of equivalents to which the claims are entitled.

1. A method comprising:
flowing an inert gas and a fluorine-containing gas into a plasma source at a first ratio;
generating a fluorine-containing plasma from the inert gas and the fluorine-containing gas by the plasma source; and
applying the fluorine containing plasma to porous carbon granules in process chamber, wherein the fluorine-containing plasma reacts with a surface of the carbon granules to form a carbon fluoride layer on the surface of the carbon granules.

2. The method of claim 1, further comprising applying a plasma power of about 50 Watts to about 100 Watts at the plasma source.

3. The method of claim 1, wherein the ratio of the inert gas to the fluorine-containing gas is about 10:1 to about 3:1.

4. The method of claim 1, wherein the fluorine-containing gas comprises F₂, NF₃, CF₃O, CF₄, SF₆, or a combination thereof, and wherein the inert gas comprises Ar.

5. The method of claim 1, wherein a first flow rate of the inert gas is about 100 to about 3500 sccm, and wherein a second flow rate of the fluorine-containing gas is about 50 to about 500 sccm.

6. The method of claim 1, further comprising maintaining the porous carbon granules at a temperature of about 25° C. to about 500° C. while applying the fluorine-containing plasma to the porous carbon granules.

7. The method of claim 1, further comprising applying a plurality of pulses of the fluorine-containing plasma to the porous carbon granules, wherein for each pulse of the plurality of pulses the fluorine-containing plasma is applied to the porous carbon granules for about 10 seconds to about 60 seconds.

8. The method of claim 7, wherein the plurality of pulses comprises about 50 to 100 pulses.

9. The method of claim 1, further comprising manufacturing one or more pressure swing adsorption beds using the carbon granules to have the carbon fluoride layer.

10. The method of claim 1, wherein the carbon fluoride layer forms on surfaces of a plurality of pores of the porous carbon granule.

11. A granule comprising:
a porous carbon body having a pore volume of about 0.1 cm3/g to about 2 cm3/g and a surface area of about 750 m2/g to about 1500 m2/g; and
a carbon fluoride layer on a surface of the porous carbon body, wherein the carbon fluoride layer is on surfaces of a plurality of pores of the porous carbon body.

12. The granule of claim 11, wherein the carbon fluoride layer comprises fluorine in at least about 90 wt %.

13. The granule of claim 11, wherein a total amount of fluorine in the granule is about 15 wt % to about 75 wt %.

14. The granule of claim 11, wherein the granule is particle free.

15. The granule of claim 11, wherein the granule is substantially free of particles.

16. The granule of claim 11, wherein the carbon fluoride layer has a composition of CFx, where x is 0.5 to 1.1.

17. The granule of claim 11, wherein the carbon fluoride layer has a thickness of about 300 nm to about 500 microns.

18. A pressure swing adsorption (PSA) filer, comprising:
a container; and
a plurality of granules in the container, each granule of the plurality of granules comprising:
a porous carbon body having a pore volume of about 0.1 cm3/g to about 2 cm3/g and a surface area of about 750 m2/g to about 1500 m2/g; and
a carbon fluoride layer on a surface of the porous carbon body, wherein the carbon fluoride layer is on surfaces of a plurality of pores of the porous carbon body.

19. The PSA filter of claim 18, wherein a total amount of fluorine in the granule is about 15 wt % to about 75 wt %.

20. The PSA filter of claim 18, wherein the granule is particle free.
